(19) United States
(12) Patent Application Publication
(10) Pub. No.: US 2014/0340091 A1
(43) Pub. Date: Nov. 20, 2014

(54) METHOD FOR MEASURING ELECTRIC CHARGE OF A BATTERY

(71) Applicant: uPI Semiconductor Corp., Hsinchu County (TW)

(72) Inventor: Sei-Ching Yang, Hsinchu County (TW)

(73) Assignee: uPI Semiconductor Corp., Hsinchu County (TW)

(21) Appl. No.: 14/253,884

(22) Filed: Apr. 16, 2014

(30) Foreign Application Priority Data
May 17, 2013 (TW) 102117580

(51) Int. Cl. G01R 31/36

(52) U.S. Cl. CPC G01R 31/3651
USPC 324/426

(57) ABSTRACT

A method for measuring electric charge of a battery is provided. The method includes the following steps. A lookup table is provided that stores a plurality of preset measurement confirmation voltages and a plurality of set electric charge. A first voltage of the battery is measured as a start point. An end point is calculated according to the lookup table and the start point. A voltage and a current of the battery are measured until a measured voltage reaches a preset measurement confirmation voltage corresponding to the end point. A set electric charge is calculated according to the lookup table from the start point to the end point. An actual electric charge is calculated from the start point to the end point. The set electric charge is corrected according to a difference between the actual electric charge and the set electric charge.

### CROSS-REFERENCE TO RELATED APPLICATION

This application claims the priority benefit of Taiwan application serial no. 102117580, filed on May 17, 2013. The entirety of the above-mentioned patent application is hereby incorporated by reference herein and made a part of this specification.

### BACKGROUND OF THE INVENTION

1. Field of the Invention

The invention relates generally to a battery measurement, and more particularly to a method for measuring electric charge of a battery.

2. Related Art

Battery capacity measurement methods using the gas gauge integrated circuit (IC) typically include the following types.

A first type of electric charge measurement method employs the coulomb counter. The coulomb counter integrates the inflow/outflow current of the battery to obtain the electric charge of the battery. However, although effective for new batteries, issues such as battery degradation and battery self-discharge cannot be overcome. Moreover, the battery capacity can only be obtained after the battery has been completely discharged.

A second type of electric charge measurement method employs an open circuit voltage (OCV) for measurement. The electric charge of the battery is monitored by using the relationship between the battery voltage and the state of charge (SOC). However, the electric charge variation is apparent only when the battery has no load. Moreover, when open circuit voltage is implemented, typically stability returns only after 30 minutes of discharging the battery, and so the electric charge measurement requires a period of wait time, which means measurement is not possible during the battery discharge.

A third type of electric charge measurement method employs internal resistance for measurement. Since the internal resistance of the battery changes with the electric charge of the battery, the internal resistance of the battery can be measured to forecast the remaining electric charge of the battery. However, the internal resistance of the battery cannot be easily measured, and the variation of the battery internal resistance increases after battery degradation.

Since all of the aforementioned methods have their shortcomings, a preferable electric charge measurement method of a battery is needed.

### SUMMARY OF THE INVENTION

Accordingly, the invention provides a method for measuring electric charge of a battery for mitigating the issues of the conventional techniques.

The invention provides a method for measuring electric charge of a battery. The method includes the following steps. A lookup table is provided storing a plurality of preset measurement confirmation voltages and a plurality of set electric charge. A first voltage of the battery is measured as a start point. An end point is calculated according to the lookup table and the start point. A voltage and a current of the battery are measured until a measured voltage reaches a preset measurement confirmation voltage corresponding to the end point. A set electric charge is calculated according to the lookup table from the start point to the end point. An actual electric charge is calculated from the start point to the end point. The set electric charge is corrected according to a difference between the actual electric charge and the set electric charge.

According to an embodiment of the invention, the preset measurement confirmation voltages include a full voltage and a cutoff voltage.

According to an embodiment of the invention, in the step of calculating the set electric charge according to the lookup table from the start point to the end point, when the start point is between a Nth voltage and a (N+1)th voltage, an interpolation operation is used to calculate the corresponding set electric charge.

According to an embodiment of the invention, the lookup table further stores a plurality of temperature information and an electric charge information corresponding to each temperature information.

According to an embodiment of the invention, the step of calculating the end point according to the lookup table and the start point includes: measuring a temperature value of the battery; and determining whether the temperature value can be found from the temperature information in the lookup table, if yes, then the preset measurement confirmation voltage corresponding to the temperature value is used as the end point, if no, then an interpolation operation is used to calculate the preset measurement confirmation voltage corresponding to the temperature value to serve as the end point.

According to an embodiment of the invention, the lookup table further stores a plurality of current information, and the step of calculating the end point according to the lookup table and the start point includes: measuring a current of the battery and calculating an average current in a preset time period; and determining whether the average current can be found from the current information in the lookup table, if yes, then the preset measurement confirmation voltage corresponding to the average current is used as the end point, if no, then an interpolation operation is used to calculate the preset measurement confirmation voltage corresponding to the average current to serve as the end point.

According to an embodiment of the invention, the preset time period is 5 seconds.

According to an embodiment of the invention, the method for measuring electric charge of the battery further includes calculating a relative state of a battery capacity (RSOC) according to the corrected set electric charge.

The invention provides another method for measuring electric charge of a battery. The method includes the following steps: obtaining a plurality of battery measurement parameters every preset time period; generating an average current according to at least one of the battery measurement parameters; calculating a set electric charge of a voltage region by using the average current in a lookup table; calculating an actual electric charge generated in the voltage region; and correcting the set electric charge according to a difference between the actual electric charge and the set electric charge.

According to an embodiment of the invention, the lookup table stores a plurality of preset average currents and related information from a full voltage to a cutoff voltage.

According to an embodiment of the invention, in the step of calculating the set electric charge of the voltage region by using the average current in the lookup table, when the average current is between a Nth voltage region and a (N+1)th voltage region, an interpolation operation is used to calculate the corresponding set electric charge.

In summary, according to embodiments of the invention, when measuring the electric charge of the battery, the set electric charge of the lookup table can be corrected according to a difference between the actual electric charge and the set electric charge of the lookup table. Moreover, the relative state of the battery capacity (RSOC) can be calculated. Embodiments of the invention do not require the battery to complete a full discharge process, nor do they require complex operations. The methods for measuring electric charge of the battery according to embodiments of the invention also improve upon the conventional open circuit voltage measurement methods, and there is no need to wait 30 minutes for the restoration time. Accordingly, the set electric charge can be corrected according to the battery characteristics, degradation results, or temperature effects, and thereby enhance the measurement efficiency.

Several exemplary embodiments accompanied with figures are described in detail below to further describe the disclosure, but they do not limit the scope or spirit of the invention.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1 is a flow diagram of a method for measuring electric charge of a battery according to an embodiment of the invention.

FIG. 2 is a flow diagram of a method for measuring electric charge of a battery according to another embodiment of the invention.

FIG. 3 is a detailed flow diagram of Step S213.

FIG. 4 is a flow diagram of a method for measuring electric charge of a battery according to another embodiment of the invention.

### DESCRIPTION OF EMBODIMENTS

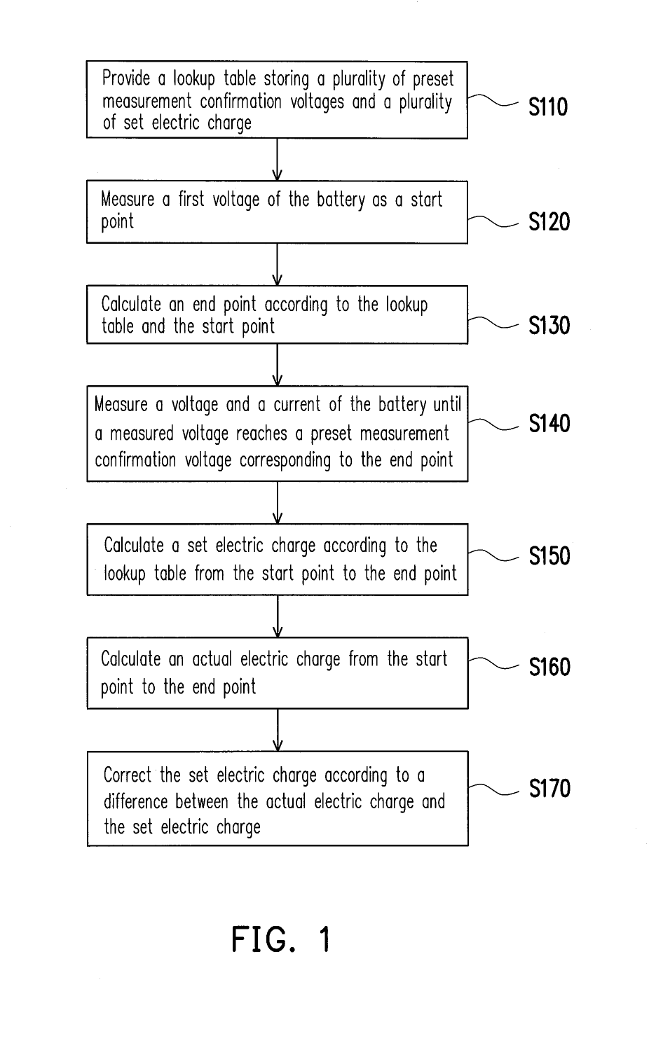

FIG. 1 is a flow diagram of a method for measuring electric charge of a battery according to an embodiment of the invention. Please refer to FIG. 1. The method of a battery according to the present embodiment includes the following steps.

As shown in Step S110, a lookup table storing a plurality of preset measurement confirmation voltages and a plurality of set electric charge is provided. The preset measurement confirmation voltages include a full voltage and a cutoff voltage. Therefore, the lookup table stores related information from the full voltage to the cutoff voltage. Moreover, the lookup table also stores a plurality of temperature information and electric charge information corresponding to each of the temperature information. For example, the lookup table may include Tables 1-3 shown below. Table 1 is a 35° C./1 C comparison table, Table 2 is a 35° C./0.7 C comparison table, and Table 3 is a 5° C./0.1 C comparison table. 1 C refers to a charge/discharge current using 1 hour as a reference. For example, “a 1 C current of a battery having a set electric charge of 1000 mAH” represents the current is 1000 mA, and “a 0.1 C current of a battery having a set electric charge of 1000 mAH” represents the current is 100 mA.

TABLE 1
(35° C./1 C Comparison Table)

| Preset Measurement | |
|---|---|
| Confirmation | Set Electric |
| Voltage (mV) | Charge (mAH) |
| 4032 | 4328 |
| (full voltage) | |
| 3932 | 152 |
| 3882 | 192 |
| 3832 | 225 |
| (assumed to be | |
| the Nth point) | |
| 3782 | 249 |
| (assumed to be | |
| the (N + 1)th point) | |
| 3732 | 282 |
| 3682 | 329 |
| 3632 | 391 |
| 3582 | 494 |
| 3532 | 688 |
| 3482 | 591 |
| 3432 | 321 |
| 3382 | 145 |
| 3331 | 80 |
| 3232 | 89 |
| 3000 | 98 |
| (cutoff voltage) | |
| 0 | 16 |

TABLE 2
(35° C./0.7 C Comparison Table)

| Preset Measurement | |
|---|---|
| Confirmation | Set Electric |
| Voltage (mV) | Charge (mAH) |
| 4100 | 4293 |
| 3990 | 305 |
| 3935 | 252 |
| 3880 | 265 |
| 3825 | 301 |
| 3770 | 355 |
| 3715 | 469 |
| 3660 | 683 |
| 3605 | 816 |
| 3550 | 453 |
| 3495 | 160 |
| 3440 | 64 |
| 3384 | 41 |
| 3330 | 32 |
| 3220 | 46 |
| 3000 | 51 |
| 0 | 17 |

TABLE 3
(5° C./0.1 C Comparison Table)

| Preset Measurement | |
|---|---|
| Confirmation | Set Electric |
| Voltage (mV) | Charge (mAH) |
| 4177 | 4253 |
| 4067 | 439 |
| 4012 | 279 |
| 3957 | 308 |
| 3902 | 350 |
| 3847 | 324 |
| 3792 | 472 |
| 3737 | 994 |
| 3682 | 481 |
| 3627 | 442 |
| 3572 | 59 |
| 3517 | 44 |
| 3462 | 35 |
| 3407 | 28 |
| 3297 | 43 |
| 3000 | 54 |
| 0 | 92 |

As shown in Step S120, a first voltage of the battery is measured as a start point. The battery is measured during the discharge process, and a first voltage of the battery measured is used as the start point. For example, 35° C./1 C/3830 mV is obtained from measuring the battery, and so the start point is set to be 3830 mV.

In Step S130, an end point is calculated according to the lookup table and the start point. For example, according to Table 1 (the 35° C./1 C comparison table), the first voltage 3830 mV is between the preset measurement confirmation voltage 3832 mV (assumed to be the Nth point) and the preset measurement confirmation voltage 3782 mV (assumed to be the (N+1)th point). In addition, the voltage value of the end point needs to be lower than the voltage value of the start point, and therefore the end point can be calculated to be 3782 mV.

As shown in Step S140, a voltage and a current of the battery are measured until a measured voltage reaches a preset measurement confirmation voltage corresponding to the end point.

In Step S150, a set electric charge is calculated according to the lookup table from the start point to the end point.

As shown in Step S160, an actual electric charge from the start point to the end point is calculated. For example, the start point (3830 mV) may be represented by SOVstart and is between the preset measurement confirmation voltage 3832 mV (assumed to be the Nth point, with set electric charge 225 mAH) and the preset measurement confirmation voltage 3782 mV (assumed to be the (N+1)th point and may be represented by SOVend or SOV_{N+1}, with set electric charge 249 mAH). As shown in equation (1), an interpolation operation can be used to calculate the set electric charge between the start point (SOVstart) to the end point (SOVend or SOV_{N+1}).

$$\frac{SOVstart - {SOV}_{N + 1}}{{SOV}_{N} - {SOV}_{N + 1}} \times {Q}_{N + 1} = \frac{3830 - 3782}{3832 - 3782} \times 249 = 239 ( mAH ) . \qquad ( 1 )$$

As shown in Step S170, the set electric charge is corrected according to a difference between the actual electric charge and the set electric charge. For example, assuming the set electric charge of the battery is originally 1000 mAH, and a difference between the actual electric charge and the set electric charge is 20 mAH less, then the corrected set electric charge Qmax of the battery is 1000 mAH subtracted by 20 mAH, or equaled to 980 mAH.

Moreover, a relative state of a battery capacity (RSOC) can be calculated according to the corrected set electric charge. For example, when the battery is discharged for 10 seconds, the average current is 700 mA, and the temperature is 35° C., then Table 2 (35° C./0.7 C comparison table) can be used for calculation. Assuming the original set electric charge of the battery is 1000 mAH, and the updated set electric charge of the battery is 980 mAH, then the equations to calculate the original RSOC and the updated RSOC can be respectively referred to equations (2) and (3).

$$\begin{matrix}Original RSOC = \frac{1000 mAH - ( 1000 mA \times 10 sec )}{1000 mAH} \times {}^{‵} 100 \% . & ( 2 ) \\ Updated RSOC = \frac{980 mAH - ( 1000 mA \times 10 sec )}{980 mAH} \times {}^{‵} 100 \% . & ( 3 )\end{matrix}$$

Overall, during the discharge process of the battery, the present embodiment corrects the set electric charge of the lookup table according to a difference between the actual electric charge and the set electric charge. Therefore, the battery capacity or the relative state of the battery capacity (RSOC) can be calculated without a full discharge process. In other words, the present embodiment does not need to add extra hardware or break off the discharge process. Moreover, the set electric charge of the battery can be used to examine the degradation level of the battery. The present embodiment does not require an enormous table to be established for recording the parameter values. Therefore, the method for measuring electric charge of the battery of the present embodiment lowers the hardware costs and the complexities of the related circuits.

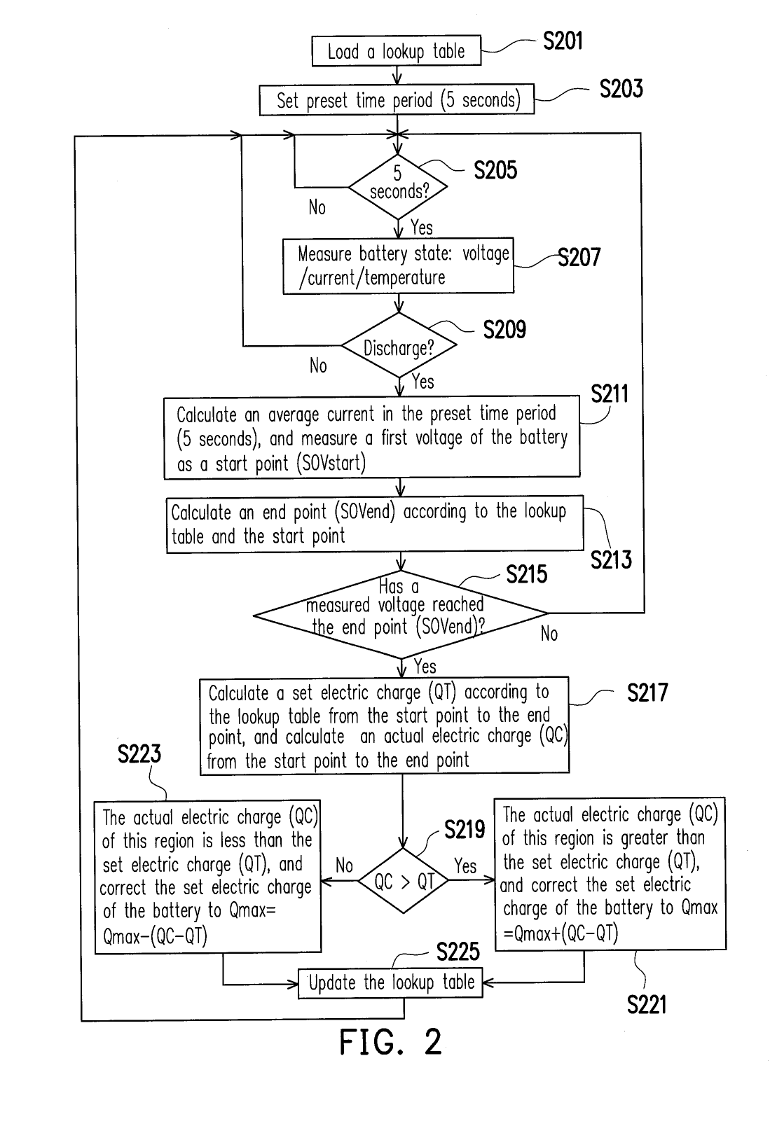

FIG. 2 is a flow diagram of a method for measuring electric charge of a battery according to another embodiment of the invention. Please refer to FIG. 2. The electric charge measurement method of the present embodiment is based on the principles of the FIG. 1 embodiment, and may include the following steps.

As shown in Step S201, a lookup table is loaded. Thereafter, as shown in Step S203, a preset time period of a timer is set, for example to 5 seconds.

In Step S205, whether 5 seconds has been reached is determined. If yes, then the process proceeds to Step S207, and if no, then the process proceeds to Step S205.

As shown in Step S207, a battery state is measured, such as voltage/current/temperature, for example. Thereafter, as shown in Step S209, whether the battery is being discharged is determined. If yes, then the process proceeds to Step S211, and if no, then the process returns to Step S205.

As shown in Step S211, an average current in the preset time period (e.g. 5 seconds) is calculated, and a first voltage of the battery is measured as a start point (may be represented by SOVstart). Thereafter, as shown in Step S213, an end point (may be represented by SOVend) is calculated according to the lookup table and the start point. As shown by Step S215, a voltage and a current of the battery are then measured until a measured voltage reaches a preset measurement confirmation voltage corresponding to the end point (SOVend). If yes, then the process proceeds to Step S217, and if no, then the process returns to Step S205.

As shown in Step S217, a set electric charge (QT) is calculated according to the lookup table from the start point to the end point, and an actual electric charge (QC) is calculated from the start point to the end point. Thereafter, as shown in Step S219, whether QC is greater than QT is determined. If yes, then the process proceeds to Step S221, and if no, then the process proceeds to Step S223.

As shown in Step S221, the actual electric charge (QC) of this region is greater than the set electric charge (QT), and the set electric charge of the battery is corrected to Qmax=Qmax+(QC−QT). Qmax on the right side of the equation is the value before the update, and Qmax on the left side of the equation is the updated value. The process then proceeds to Step S225.

As shown in Step S223, the actual electric charge (QC) of this region is less than the set electric charge (QT), and the set electric charge of the battery is corrected as Qmax=Qmax−(QC−QT). Qmax on the right side of the equation is the value before the update, and Qmax on the left side of the equation is the updated value. The process then proceeds to Step S225.

As shown in Step S225, the lookup table is updated. The process then returns to Step S205, and another electric charge measurement process is performed (e.g., from Steps S205-S225).

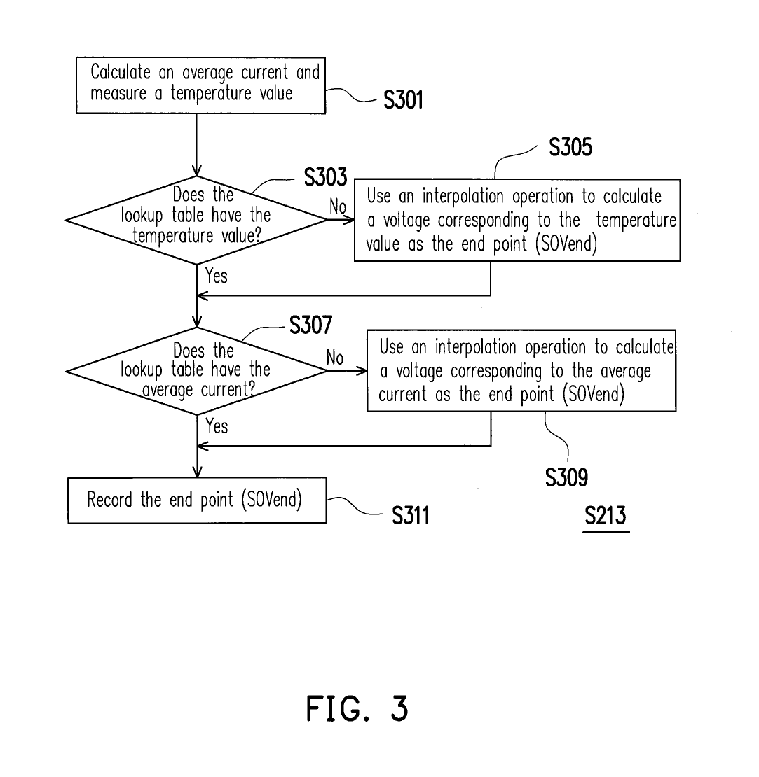

Description of each detailed process in Step S213 is provided hereafter. Please refer to FIG. 3. Step S213 which calculates the end point according to the lookup table and the start point further includes Steps S301-S311 described below.

As shown in Step S301, an average current is calculated and a temperature value is measured. Thereafter, as shown in Step S303, whether the lookup table has the above temperature value is determined. If yes, then the process proceeds to Step S307, and if no, then the process proceeds to Step S305.

As shown in Step S305, an interpolation operation is used to calculate a voltage corresponding to the above temperature value as the end point (SOVend), and the process proceeds to Step S307.

Thereafter, as shown in Step S307, whether the lookup table has the above average current is determined. If yes, then the process proceeds to Step S311, and if no, then the process proceeds to Step S309.

As shown in Step S309, an interpolation operation is used to calculate a voltage corresponding to the above average current as the end point (SOVend), and the process proceeds to Step S311.

As shown in Step S311, the end point (SOVend) is recorded according to the values calculated or found from the lookup table.

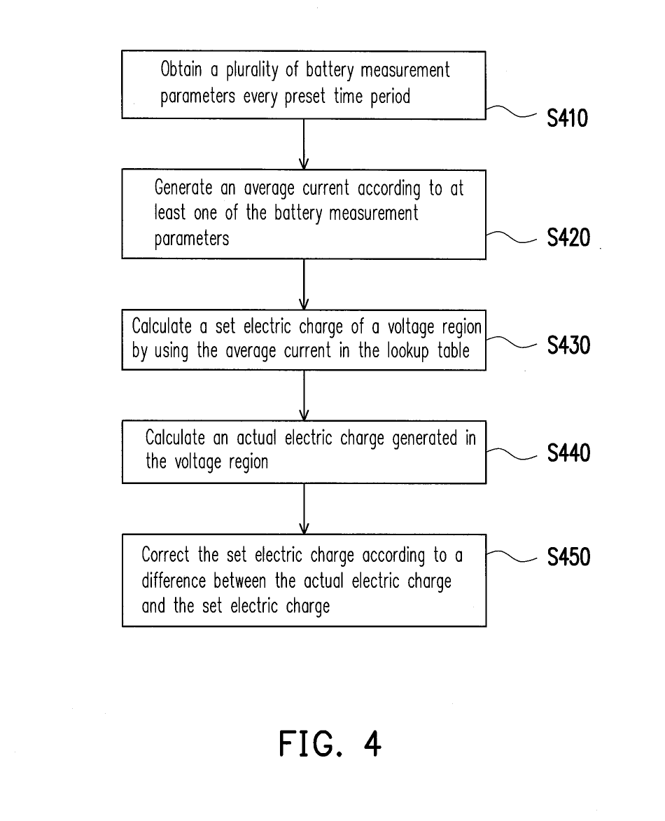

FIG. 4 is a flow diagram of a method for measuring electric charge of a battery according to another embodiment of the invention. Please refer to FIG. 4. The electric charge measurement method of the present embodiment may include the following steps.

As shown in Step S410, a plurality of battery measurement parameters are obtained every preset time period. For example, the preset time period may be 5 seconds, and the battery measurement parameters may include voltages, currents, temperatures, electric charge, although not limited thereto.

As shown in Step S420, an average current is generated according to at least one of the battery measurement parameters.

As shown in Step S430, a set electric charge of a voltage region is calculated by using the average current in the lookup table. For example, when the average current is 100 mA and the temperature is 5° C., the set electric charge can be calculated according to Table 3 (5° C./0.1 C comparison table). The related detailed procedures can be performed in accordance with the afore-described Steps S120-S150 and Steps S211-S217.

As shown in Step S440, an actual electric charge generated in the voltage region is calculated. The related detailed procedures can be performed in accordance with the afore-described Step S160 and Step S217.

As shown in Step S450, the set electric charge is corrected according to a difference between the actual electric charge and the set electric charge. The related detailed procedures can be performed in accordance with the afore-described Step S219 and Step S225.

In view of the foregoing, according to embodiments of the invention, when measuring the electric charge of a battery, the set electric charge of the lookup table can be corrected according to a difference between the actual electric charge and the set electric charge of the lookup table. Moreover, the relative state of the battery capacity (RSOC) can be calculated. Embodiments of the invention do not require the battery to complete a full discharge process, nor do they require complex operations. The methods for measuring electric charge of the battery according to embodiments of the invention also improve upon the conventional open circuit voltage measurement method, and there is no need to wait 30 minutes for the restoration time. Accordingly, the set electric charge can be corrected according to the battery characteristics, degradation results, or temperature effects, and thereby enhance the measurement efficiency.

It will be apparent to those skilled in the art that various modifications and variations can be made to the structure of the disclosure without departing from the scope or spirit of the invention. In view of the foregoing, it is intended that the disclosure cover modifications and variations of this invention provided they fall within the scope of the following claims and their equivalents.

Moreover, any embodiment or claim scope of the invention does not need to achieve all of the goals, advantages, or features disclosed by the invention. Furthermore, the abstract and title are used only to facilitate patent search, and not for limiting the claim scope of the invention.

What is claimed is:

1. A method for measuring electric charge of a battery, comprising:
providing a lookup table storing a plurality of preset measurement confirmation voltages and a plurality of set electric charge;
measuring a first voltage of the battery as a start point;
calculating an end point according to the lookup table and the start point;
measuring a voltage and a current of the battery until a measured voltage reaches a preset measurement confirmation voltage corresponding to the end point;
calculating a set electric charge according to the lookup table from the start point to the end point;
calculating an actual electric charge from the start point to the end point; and
correcting the set electric charge according to a difference between the actual electric charge and the set electric charge.

2. The method according to claim 1, wherein the preset measurement confirmation voltages comprise a full voltage and a cutoff voltage.

3. The method according to claim 1, wherein in the step of calculating the set electric charge according to the lookup table from the start point to the end point, when the start point is between a Nth voltage and a (N+1)th voltage, an interpolation operation is used to calculate the corresponding set electric charge.

4. The method according to claim 1, wherein the lookup table further stores a plurality of temperature information and an electric charge information corresponding to each temperature information.

5. The method according to claim 4, wherein the step of calculating the end point according to the lookup table and the start point comprises:
measuring a temperature value of the battery; and
determining whether the temperature value can be found from the temperature information in the lookup table, if yes, then the preset measurement confirmation voltage corresponding to the temperature value is used as the end point, if no, then an interpolation operation is used to calculate the preset measurement confirmation voltage corresponding to the temperature value to serve as the end point.

6. The method according to claim 1, wherein the lookup table further stores a plurality of current information, and the step of calculating the end point according to the lookup table and the start point comprises:
measuring a current of the battery and calculating an average current in a preset time period; and
determining whether the average current can be found from the current information in the lookup table, if yes, then the preset measurement confirmation voltage corresponding to the average current is used as the end point, if no, then an interpolation operation is used to calculate the preset measurement confirmation voltage corresponding to the average current to serve as the end point.

7. The method according to claim 6, wherein the preset time period is 5 seconds.

8. The method according to claim 1, further comprising:
calculating a relative state of a battery capacity according to the corrected set electric charge.

9. A method for measuring electric charge of a battery, comprising:
obtaining a plurality of battery measurement parameters every preset time period;
generating an average current according to at least one of the battery measurement parameters;
calculating a set electric charge of a voltage region by using the average current in a lookup table;
calculating an actual electric charge generated in the voltage region; and
correcting the set electric charge according to a difference between the actual electric charge and the set electric charge.

10. The method according to claim 9, wherein the lookup table stores a plurality of preset average currents and related information from a full voltage to a cutoff voltage.

11. The method according to claim 10, wherein in the step of calculating the set electric charge of the voltage region by using the average current in the lookup table, when the average current is between a Nth voltage region and a (N+1)th voltage region, an interpolation operation is used to calculate the corresponding set electric charge.

12. The method according to claim 9, wherein the lookup table further stores a plurality of temperature information and an electric charge information corresponding to each temperature information.

13. The method according to claim 9, wherein the preset time period is 5 seconds.

14. The method according to claim 9, further comprising:
calculating a relative state of a battery capacity according to the corrected set electric charge.
